(19) United States
(12) Patent Application Publication
(10) Pub. No.: US 2025/0054751 A1
(43) Pub. Date: Feb. 13, 2025

(54) ALD PULSE SEQUENCE ENGINEERING FOR IMPROVED CONFORMALITY FOR LOW TEMP PRECURSORS

(71) Applicant: Lam Research Corporation, Fremont, CA (US)

(72) Inventors: Awnish Gupta, Hillsboro, OR (US); Bart J. Van Schravendijk, Palo Alto, CA (US); Aaron Blake Miller, West Linn, OR (US); Jon Henri, West Linn, OR (US)

(21) Appl. No.: 18/720,153

(22) PCT Filed: Dec. 15, 2022
(86) PCT No.: PCT/US2022/053014

§ 371 Date: Jun. 14, 2024

Related U.S. Application Data
(60) Provisional application No. 63/265,694, filed on Dec. 17, 2021.

(51) Int. Cl. H01L 21/02; C23C 16/34; C23C 16/44; C23C 16/455

(52) U.S. Cl. CPC H01L 21/0228; C23C 16/345; C23C 16/4408; C23C 16/45542; H01L 21/0217

(57) ABSTRACT

The present disclosure relates to methods, systems, and apparatuses for depositing films. In particular, a film is deposited using an atomic layer deposition process where some steps of the ALD process are performed at a temperature above a pyrolysis temperature of a film precursor.

### INCORPORATED BY REFERENCE

An application data sheet is filed concurrently with this specification as part of the present application. Each application that the present application claims benefit of or priority to as identified in the concurrently filed application data sheet is incorporated by reference herein in its entirety and for all purposes.

### BACKGROUND

Semiconductor device fabrication may involve deposition of silicon nitride films. Silicon nitride thin films have unique physical, chemical, and mechanical properties and thus are used in a variety of applications. For example, silicon nitride films may be used in diffusion barriers, gate insulators, sidewall spacers, encapsulation layers, strained films in transistors, and the like.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of depositing films. In one aspect of the embodiments herein, a method of depositing a film is provided, the method including: providing a substrate in a process chamber; and performing one or more cycles of an atomic layer deposition (ALD) process, wherein each of the one or more cycles of the ALD process includes: (a) exposing the substrate to a precursor, wherein the substrate is at a first temperature during at least a portion of (a), wherein the first temperature is below a pyrolysis temperature of the precursor; and (b) exposing the substrate to one or more reactants, wherein during at least a portion of (b) the substrate is at a second temperature above the pyrolysis temperature. In some embodiments, during (b) the process chamber is at a first pressure, and the method further includes, before (a): (c) exposing the substrate to a purge gas, wherein during (c) the process chamber is at a second pressure less than the first pressure. In some embodiments, during (c) the temperature of the substrate decreases from the second temperature to the first temperature. In some embodiments, the first pressure is at least about 5 Torr, and the second pressure is less than about 1 Torr. In some embodiments, the second pressure is less than about 0.1 Torr. In some embodiments, the process chamber is at a third pressure during (a), and the third pressure is less than the first pressure.

In some embodiments, the purge gas includes an inert gas. In some embodiments, the purge gas includes H₂. In some embodiments, the duration of (c) is at least about 5 seconds. In some embodiments, the second temperature is at least about 600° C. In some embodiments, the pyrolysis temperature is between about 500° C. and about 600° C. In some embodiments, (b) is performed in the presence of a plasma. In some embodiments, a power of the plasma is at least about 5000 W. In some embodiments, the precursor is a silicon-containing precursor. In some embodiments, the precursor is a carbon-containing precursor. In some embodiments, the one or more reactants include a nitrogen-containing reactant. In some embodiments, the one or more reactants include an oxygen-containing reactant. In some embodiments, the ALD process forms a conformal film. In some embodiments, the conformal film is a silicon nitride film. In some embodiments, the substrate includes features having an aspect ratio of at least about 30:1. In some embodiments, the process chamber includes a pedestal, and the pedestal temperature is about the second temperature during (a). These and other features of the disclosed embodiments will be described in detail below with reference to the associated drawings.

### BRIEF DESCRIPTION OF DRAWINGS

FIGS. 1A and 1B present examples of sidewall thickness based on embodiments described herein.

FIG. 2 presents a flowchart of an example embodiment herein.

FIG. 3 presents pressure and temperature charts for atomic layer deposition (ALD) processes according to various embodiments herein.

FIGS. 4A and 4B present examples of determining a pyrolysis temperature according to various embodiments herein.

FIGS. 5-8 are schematic diagrams of examples of process chambers for performing methods in accordance with disclosed embodiments.

### DETAILED DESCRIPTION

Semiconductor fabrication processes often involve deposition of silicon nitride material. In one example, silicon nitride may be used in semiconductor device fabrication as diffusion barriers, gate insulators, sidewall spacers, liners, strained films in transistors, etch stop layers, and encapsulation layers. Conformal silicon nitride layers may also be used in other applications. For example, silicon nitride may be used during fabrication of memory structures.

This disclosure relates to methods for depositing a film at high temperatures using an atomic layer deposition (ALD) process. Typically, an ALD cycle includes operations to deliver and adsorb at least one reactant to the substrate surface, and then react the adsorbed reactant with one or more reactants to form a layer of film. As an example, a silicon nitride deposition cycle may include the following operations: (i) delivery/adsorption of a silicon-containing precursor, (ii) purging of the silicon-containing precursor from the chamber, (iii) delivery of a nitrogen-containing reactant or nitrogen-containing gas, and (iv) purging of the nitrogen-containing reactant from the chamber.

Unlike a chemical vapor deposition (CVD) technique, ALD processes use surface-mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber configured to house a substrate. Molecules of this first precursor are adsorbed onto the substrate surface, including chemisorbed species and/or physisorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. This operation may be surface-mediated, in that only a single layer or partial layer of the first precursor saturates the substrate surface. After a first precursor dose, the chamber is then evacuated to remove most or all of first precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A reactant, such as a nitrogen-containing reactant, is introduced to the chamber so that some of these molecules react with the first precursor adsorbed on the surface. In some processes, the reactant reacts immediately with the adsorbed first precursor. In some embodiments, a plasma is ignited when the reactant is introduced to the chamber. The chamber may then be evacuated again to remove unbound second reactant molecules. As described above, in some embodiments the chamber may not be completely evacuated. Additional ALD cycles may be used to build film thickness.

Generally, depositing films at higher temperatures (e.g., above 600° C.) results in better film quality. Films deposited at higher temperatures typically have fewer impurities, higher densities, lower wet etch rates, less leakage current and a higher breakdown voltage compared to films deposited at lower temperatures. In some embodiments, a film deposited at a low temperature may be annealed at a higher temperature to improve film properties. However, in surface-mediated deposition processes such as atomic layer deposition (ALD), a precursor may thermally decompose (undergo pyrolysis) at such higher temperatures. This may add a chemical vapor deposition (CVD) component to the ALD process, which is undesirable.

Pyrolysis may occur with or without any catalyst, including in the presence of an inert gas, where the elevated temperature breaks chemical bonds in the precursor. In the context of ALD, some precursors that would otherwise adsorb onto the substrate surface and saturate may decompose above a pyrolysis temperature of the precursor. This pyrolysis may inhibit the saturation mechanism of ALD, as additional molecules of the precursor may then adsorb onto the decomposed precursors. In effect, above the pyrolysis temperature of a silicon-containing precursor, the initial step of an ALD cycle to deliver/adsorb a silicon-containing precursor may have a chemical vapor deposition component that results in deposition of a silicon film. Pyrolysis may cause the chemical bonds to groups that limit additional adsorption of precursor to break, allowing for additional adsorption/decomposition of precursor. For example, a silicon-containing precursor like di-chlorosilane (DCS) may undergo pyrolysis to break the silicon-chlorine bonds, allowing additional DCS to adsorb (and subsequently thermally decompose), resulting in the deposition of a silicon film with chlorine contaminants.

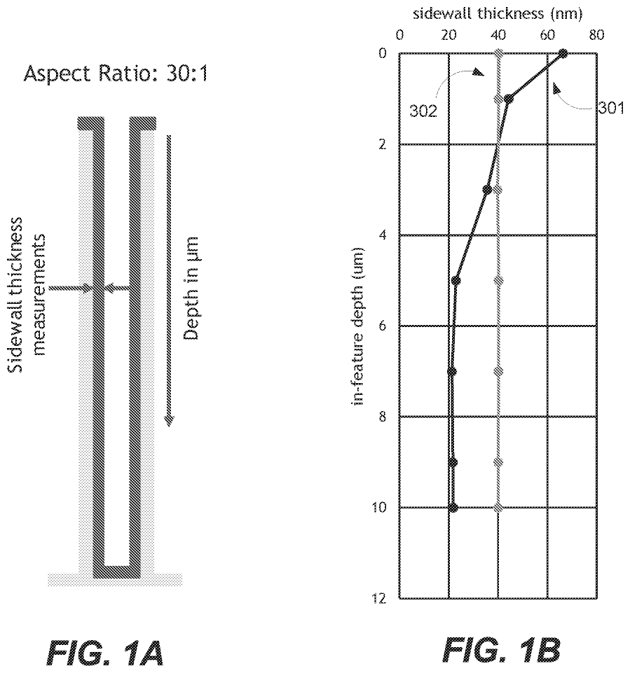

FIG. 1A illustrates a substrate feature in which a film may be deposited. In some implementations, a film can be deposited in a feature having a depth and a width, in which the aspect ratio of the depth to width is about 30:1. The deposited film can be characterized by its deposited thickness on the sidewall, and the deposited thickness at the top of the feature and at the bottom of the feature can be compared to provide a measurement of conformality.

FIG. 1B shows a film deposited using BTBAS (Bis(t-butylamino)silane) as a silicon-containing precursor. Film 301 was deposited using a thermal ALD process at a temperature above the pyrolysis temperature of BTBAS (which is about 550° C.). Film 302 was deposited using a thermal ALD process at a temperature below the pyrolysis temperature. As shown in FIG. 1B, film 302 is conformal, while film 301 has additional deposition near the top of the feature, reducing conformality from 100% to about 30%, which is undesirable. the excess deposition at the top of the feature in film 301 is attributed to pyrolysis of BTBAS, resulting in a CVD component that is not surface-mediated.

To address this CVD component, an atomic layer deposition (ALD) process may deliver precursor at a lower temperature than a conversion process where the substrate is exposed to a reactant. In particular, the temperature of the substrate may be lowered below a pyrolysis temperature of a precursor during a precursor delivery operation, and the temperature of the substrate may then be raised above the pyrolysis temperature during a subsequent operation to react the precursor with a reactant. In some embodiments, the deposited layer is a silicon nitride film. However, the techniques described herein may be used with other precursors, e.g., carbon-containing precursors or silicon-containing precursors, that have a pyrolysis temperature below a temperature of a processing operation.

In some embodiments, the ALD process may be performed in a process chamber having a pedestal on which a substrate is placed during processing operations. The pedestal may include heating elements that can be controlled to increase the temperature of the substrate during the processing operations to, e.g., 600° C. or greater. While the temperature of the heating elements may be decreased to allow the temperature of the substrate to decrease, this type of cooling is too slow to be acceptable for throughput.

To cool the substrate within acceptable time constraints, in some embodiments the pressure of the process chamber is decreased while flowing a purge gas. Decreasing the pressure of the process chamber may cause an immediate decrease in the temperature of the substrate, even if the pedestal is maintained at a higher temperature. Without being bound by theory, decreasing the pressure of the process chamber may cause a vacuum cooling effect on the wafer. Vacuum cooling of the wafer may be performed while flowing a purge gas. Based on the pressure of the process chamber and a duration of flowing purge gas at the decreased pressure, the temperature of the substrate may be tuned prior to a precursor delivery step. By cooling the wafer below a pyrolysis temperature of the precursor, the subsequent precursor delivery step may saturate the surface of the substrate without pyrolysis occurring, resulting in a surface-mediated step that does not have a CVD component. The temperature of the wafer may then be increased before delivery of a reactant. A purge gas may comprise any inert gas, e.g., N₂, Argon, Helium, Xenon, etc. In some embodiments, H₂ may be co-flowed with the inert gas. Co-flowing hydrogen may increase the rate of temperature decrease.

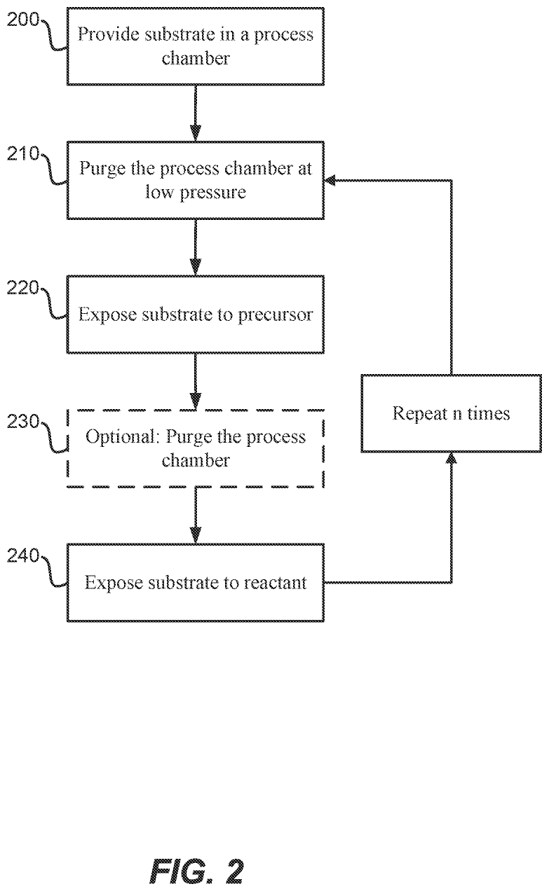

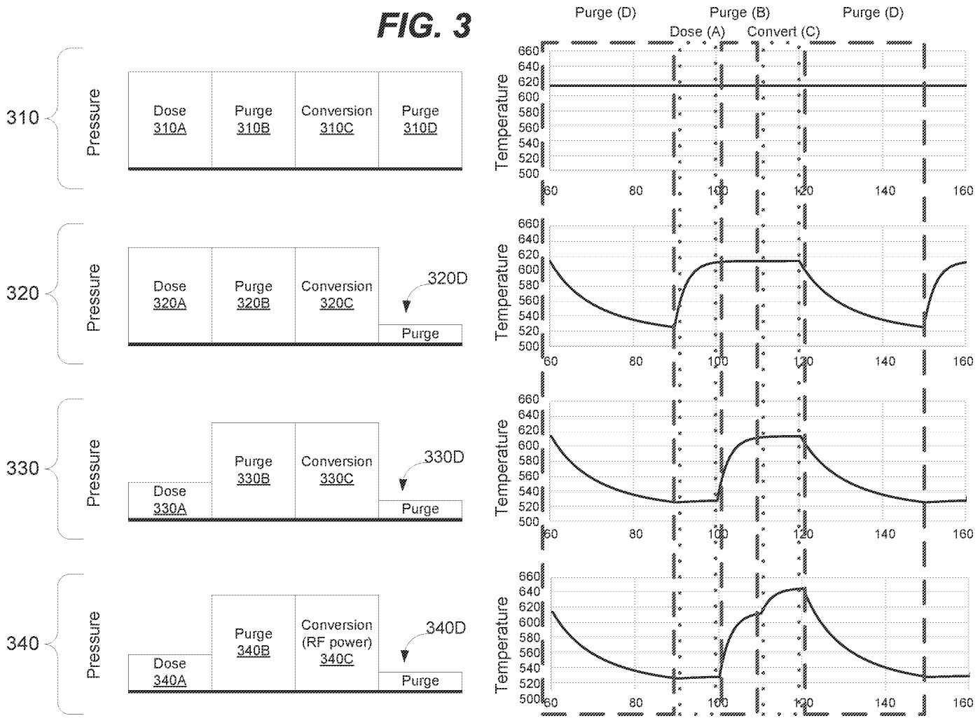

FIG. 2 provides a flowchart of an ALD process according to various embodiments herein. FIG. 2 may be understood with reference to FIG. 3, which provides timing diagrams for pressure and temperature of various operations of an ALD cycle. The concept of an ALD “cycle” is relevant to the discussion of various embodiments herein. Generally, a cycle is the minimum set of operations used to perform a surface deposition reaction one time. The result of one cycle is production of at least a partial silicon nitride film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations. ALD cycles may be repeated n times to build film thickness.

The film can be provided on any useful substrate. The substrate may be a silicon wafer, e.g., a 200-mm wafer, a 300-mm wafer, or a 450-mm wafer, including wafers having one or more layers of material, such as dielectric, conducting, or semi-conducting material deposited thereon. The substrate can include structures, such as high aspect ratio (HAR) structures, as described herein.

Substrates may have “features” such as via or contact holes, which may be characterized by one or more of narrow and/or re-entrant openings, constrictions within the feature, and high aspect ratios. The feature may be formed in one or more of the above described layers. One example of a feature is a hole or via in a semiconductor substrate or a layer on the substrate. In some embodiments, the feature may have an aspect ratio of at least about 2:1, at least about 4:1, at least about 6:1, at least about 10:1, or higher. The feature may also have a dimension near the opening, e.g., an opening diameter or line width of between about 10 nm to 500 nm, for example between about 25 nm and about 300 nm. Disclosed methods may be performed on substrates with features having an opening diameter less than about 150 nm. A feature via or trench may be referred to as an unfilled feature or a feature. A feature may have a re-entrant profile that narrows from the bottom, closed end, or interior of the feature to the feature opening.

In any method herein, an initial operation can include providing a substrate to a process chamber. The process chamber may be set to a chamber pressure between about 10 mTorr and about 30 Torr, or between about 1 to 3 Torr or between about 0.5 to 22 Torr. The chamber pressure may change during operations of an ALD process as described herein.

The substrate may be heated to a substrate temperature between about 25° C. and about 900° C., or between about 500° C. and about 700° C. It will be understood that substrate temperature as used herein refers to the temperature of the substrate, and that the temperature of the substrate may be different than the temperature the pedestal holding the substrate is set at and that in some embodiments, the substrate when provided to the process chamber on the pedestal may be heated to the desired substrate temperature prior to processing the substrate. The pedestal temperature may be the same throughout operations as described herein, while the substrate temperature may change during operations of an ALD process as described herein.

Returning FIG. 2, in operation 200, the substrate is provided in a process chamber. In some embodiments, the substrate may be heated until it is a temperature of a pedestal in the process chamber supporting the substrate. The temperature of the pedestal may be a first temperature that is, e.g., greater than about 550° C., greater than about 600° C., greater than about 650° C., greater than about 700° C., between about 550° C. and about 700° C. In some embodiments, the first temperature is greater than a pyrolysis temperature of a precursor to be delivered to the substrate. In some embodiments, during operation 200 the pressure of the process chamber is at least about 1 Torr, at least about 5 Torr, or at least about 10 Torr.

In operation 210 the substrate is exposed to purge gas at a low pressure. In some embodiments, low pressure may be any pressure lower than the pressure of the process chamber in operation 200. In some embodiments, low pressure may be less than about 1 Torr, less than about 0.5 Torr, less than about 0.1 Torr, or less than about 10 mTorr. A duration of operation 210 may be based on the pyrolysis temperature of the precursor. Generally, a longer duration of low pressure purge further decreases the temperature of the substrate. In some embodiments, the duration of the low pressure purge may be at least about 1 second, at least about 5 seconds, at least about 10 seconds, at least about 20 seconds, at least about 30 seconds, or between about 1 second and 30 seconds. In some embodiments, the duration of operation 210 is based on the time required for the substrate temperature to decrease below the pyrolysis temperature. At the end of operation 210 the substrate may be at a second temperature, where the second temperature is lower than the first temperature. In some embodiments, the second temperature is below the pyrolysis temperature of the precursor to be delivered. In some embodiments, during operation 210 the temperature of the substrate decreases by at least about 50° C., at least about 70° C., at least about 100° C., at least about 150° C., or between about 50° C. and about 150° C.

The purge gas can be flowed to a chamber housing the substrate at a flow rate between about 1000 sccm and about 40000 sccm (e.g., about 1000 to 2000 sccm). In some embodiments, the purge gas may be selected based on its thermal conductivity or co-flowed with other gases having a higher thermal conductivity. A higher thermal conductivity gas will increase the rate cooling of the chamber by absorbing more thermal energy during a purge operation. Hydrogen and helium gases are notable for a higher thermal conductivity (about 0.182 and 0.151 W/mK at 300K), compared to other inert gases such as Argon or N₂. In some embodiments, the purge gas may be co-flowed with H₂. Co-flowing hydrogen with an inert gas may cause the substrate temperature to decrease more rapidly during operation 210 compared to flowing just an inert gas, which may decrease the duration of operation 210 required to cool the substrate below a pyrolysis temperature of a precursor and thus improve throughput.

In operation 220 the substrate is exposed to the precursor. The precursor adsorbs onto a surface of the substrate. The precursor may be a silicon-containing precursor, a carbon-containing precursor, or other precursors. The temperature of the substrate may be at the second temperature for at least a portion of operation 220. In some embodiments, the temperature of the substrate is at about the second temperature throughout operation 220. In some embodiments, the temperature of the substrate is about the second temperature at the beginning of operation 220, and the temperature of the substrate increases during operation 220. In some embodiments, the substrate may be exposed to more than one precursor. In such embodiments, each precursor may have a different pyrolysis temperature, where the second temperature is based on the lowest pyrolysis temperature. In some embodiments, the second temperature may be between the pyrolysis temperatures of the more than one precursors.

In some embodiments, the precursor is flowed to a chamber housing the substrate at a flow rate between about 100 sccm and about 5000 sccm (e.g., about 100 to 2000 sccm). The precursor can be flowed for any useful period (e.g., about 0.1 to 10 seconds) and any useful pressure (e.g., about 1 to 25 Torr).

During operation 220, an inert gas may be co-flowed with the precursor. The inert gas may nitrogen (N₂), argon (Ar), or any other listed herein. The inert gas may be provided to assist with pressure and/or temperature control of the process chamber, evaporation of a liquid reactant, more rapid delivery of the reactant, and/or as a purge gas for removing process gases from the process chamber and/or process chamber plumbing. In some embodiments, the inert gas is flowed to a chamber housing the substrate at a flow rate between about 100 sccm and about 5000 sccm (e.g., about 500 to 2000 sccm). Flow of the inert gas with the precursor can allow for dilution of the precursor, as well as pressure stability during operation.

In some embodiments operation 220 may be performed at a higher process chamber pressure than operation 210, e.g., at the pressure of the process chamber during operation 200. In other embodiments, the pressure of the process chamber may be at a third pressure between the pressuring during operation 200 and 210. This third pressure may be based on maintaining the temperature of the substrate at the second temperature below the pyrolysis temperature of the precursor during operation 220. In some embodiments, the third pressure may be about 1 Torr, or between about 1 Torr and about 10 Torr.

In operation 230, the process chamber is optionally purged to remove precursor molecules that did not adsorb onto the substrate surface. In some embodiments the pressure of the process chamber is increased during operation 230 to facilitate increasing the temperature of the substrate for a subsequent conversion operation (240).

Purging the chamber may involve flowing a purge gas or a sweep gas, which may be a carrier gas used in other operations or may be a different gas. In some embodiments, purging may involve evacuating the chamber. Examples of purge gases include argon (Ar), nitrogen (N₂), hydrogen (H₂), helium (He), oxygen (O₂), krypton (Kr), xenon (Xe), neon (Ne), and combinations thereof. In various embodiments, the purge gas is an inert gas. The purge gas may include one or more gases. In some embodiments, operation 230 may include one or more evacuation subphases for evacuating the process chamber. Alternatively, it will be appreciated that operation 230 may be omitted in some embodiments. Operation 230 may have any suitable duration, such as between about 0 seconds and about 60 seconds, for example about 0.01 seconds. In some embodiments, increasing a flow rate of one or more purge gases may decrease the duration of operation 230. For example, a purge gas flow rate may be adjusted according to various reactant thermodynamic characteristics and/or geometric characteristics of the process chamber and/or process chamber plumbing for modifying the duration of operation 230. In one non-limiting example, the duration of a purge phase may be adjusted by modulating purge gas flow rate. This may reduce deposition cycle time, which may improve substrate throughput. After a purge, the precursor molecules remain adsorbed onto the substrate surface.

The purge gas can be flowed to a process chamber housing the substrate at a flow rate between about 1000 sccm and about 40000 sccm (e.g., about 1000 to 2000 sccm). The purge gas can be flowed for any useful period (e.g., about 0.1 to 10 seconds) and any useful pressure (e.g., about 0.5 to 25 Torr).

In operation 240, the substrate is exposed to a reactant gas with or without a plasma to react with the adsorbed precursor and form a film. In various embodiments, the reactant gas may comprise one or more reactants, including nitrogen- or oxygen-containing reactants. The nitrogen- or oxygen-containing reactant can be flowed to a process chamber housing the substrate at a flow rate between about 1000 sccm and about 40000 sccm (e.g., about 2000 to 10000 sccm). The reactant can be flowed for any useful period (e.g., about 0.5 to 40 seconds) and any useful pressure (e.g., about 1 to 25 Torr). In some embodiments, the pressure of the process chamber during operation 240 is at least about 5 Torr or at least about 10 Torr. The pressure of the process chamber during operation 240 may be greater compared to operations 210 or 220 in order to maintain a higher temperature of the substrate during operation 240. In some embodiments, operation 240 may be a thermal conversion operation to react the one or more reactants with the adsorbed precursor.

The reactant gas can be used with a push gas or a carrier gas. The push gas or the carrier gas may be an inert gas, such as those described herein. The push gas or carrier gas can be flowed to a chamber housing the substrate at a flow rate between about 100 sccm and about 5000 sccm (e.g., about 500 to 2000 sccm). The push gas or carrier gas can be flowed for any useful period (e.g., about 0.5 to 40 seconds) and any useful pressure (e.g., about 1 to 25 Torr).

In yet other embodiments, the reactant can further include co-flow with a reducing gas. Non-limiting reducing gases can include hydrogen (H₂). In one non-limiting instance, operation 220 includes a nitrogen-containing reactant (e.g., NH₃ or N₂), a reducing gas (e.g., H₂), and optionally an inert gas (e.g., N₂). The reducing gas can be flowed to a chamber housing the substrate at a flow rate between about 0 and about 10000 sccm (e.g., about 0 to 5000 sccm). The reducing gas can be flowed for any useful period (e.g., about 0.5 to 40 seconds) and any useful pressure (e.g., about 1 to 25 Torr).

In some embodiments, operation 240 may comprise exposing the substrate to an energetic species (e.g., a radical species). In various embodiments, a radical species is generated from a source gas, in which the source gas includes, e.g., an oxygen and/or a nitrogen atom. In yet other embodiments, the source gas can further include co-flow with a reducing gas. In some embodiments, the radical species is a NH* radical species or a NR* radical species, in which R is H, aliphatic, aromatic, heteroaliphatic, or heteroaromatic. The NH* radical species can be generated in any useful manner, such as by NH₃, N₂/NH₃, or N₂/H₂ plasma. During plasma generation, any useful process conditions can be modified, in which conditions can include pressure, gas mixture ratio, and plasma power (e.g., in which higher power can provide a higher radical flux).

Other radical species for depositing a SiN film can include elemental nitrogen radicals, ammonia radicals, and amine radicals. Examples of amine radicals include but are not limited to radicals of methylamine, dimethylamine, and aniline. In some embodiments, all or substantially all the radicals can be in the ground state, e.g., at least about 90% or 95% of the radicals adjacent the substrate are in the ground state. In some embodiments, as discussed in further detail below, the radical species can be produced by a remote plasma source.

In particular embodiments, the radical species is formed with a plasma formed from a combination of N₂ with NH₃ or a combination of N₂ with H₂. As can be seen, a plasma can be formed by employing only a nitrogen-containing reactant or a combination of a nitrogen-containing reactant with a reducing gas (e.g., such as hydrogen or H₂). Furthermore, an inert gas can be employed with the nitrogen-containing reactant. The plasma can be delivered to a chamber housing the substrate at a flow rate between about 0 and about 10000 sccm (e.g., about 0 to 5000 sccm). The reducing gas can be flowed for any useful period (e.g., about 0.5 to 40 seconds) and any useful pressure (e.g., about 0.5 to 25 Torr).

In one embodiment, plasma is formed in the presence of a first nitrogen-containing reactant (e.g., having a flow rate of about 20 to 500 sccm), an inert gas (e.g., having a flow rate of about 1000 to 40000 sccm), and a reducing gas (e.g., having a flow rate of about 0 to 200 sccm). In particular embodiments, the plasma is formed in the presence of a first nitrogen-containing reactant including NH₃ (e.g., having a flow rate of about 50 to 250 sccm), an inert gas including N₂ (e.g., having a flow rate of about 5000 to 25000 sccm), and a reducing gas including H₂ (e.g., having a flow rate of about 0 to 100 sccm).

The plasma power may be between about 75 W and about 12000 W per 300 mm wafer surface area. The plasma may be generated remotely (such as in a remote plasma generator) or directly in a chamber housing the substrate (i.e., in situ). The in situ plasma may be ignited at a power per substrate area between about 0.2122 W/cm² and about 2.122 W/cm². For example, the power may range from about 600 W to about 6000 W for a chamber processing four 300 mm wafers. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process.

During operation 240, it will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that a nitrogen- or oxygen-containing reactant or a source gas is ignited in a remote plasma generator upstream of the station, then delivered to the station where the substrate is housed.

Operations 210-240 may be repeated in sufficient cycles to deposit a desired thickness of film, e.g., a silicon oxide or silicon nitride film. Any suitable number of deposition cycles may be included in an ALD process to deposit a desired film thickness. For example, about 20 to about 40 deposition cycles may be performed to deposit a silicon nitride film on the substrate using disclosed embodiments.

FIG. 3 presents example timing diagrams of temperature and pressure of various ALD cycles according to embodiments herein. Each of diagrams 310-340 correspond to a different set of ALD cycles. Diagram 310 illustrates a typical isobaric ALD process, where each step of dose, purge, conversion, and purge are performed at the same pressure. Diagrams 320-340 illustrate various low pressure purge ALD processes corresponding to the flowchart of FIG. 2. For diagram 310, dose phase 310A refers to exposing the substrate to a precursor as described herein. Conversion phase 310C refers to exposing the substrate to a reactant as described herein. Purge phases 310B and 310D refer to exposing the substrate to a purge gas without any precursor or reactants. In diagram 310, both purge phases are performed at the same pressure. In some embodiments, purge phases may be low pressure purge operations as described herein (particularly a purge operation before a dose operation), while some purge operations may not be low pressure purge operations.

The time/temperature diagram is marked with phases that correspond with phases 310A-D. In particular, the leftmost phase marked “Purge (D)” corresponds with purge phases 310D-340D. As ALD is a cyclic process, purge phase 310D-340D may be performed before dose phase 310A-340A.

Diagram 310 illustrates an isobaric ALD process where all operations are performed at the same process chamber pressure, e.g., 10 Torr. The substrate may correspondingly maintain the same temperature, e.g., 610° C., and thus may have a CVD component during the dose phase, which is undesirable. The temperature of the substrate and the pressure of the process chamber do not change during any phase of the ALD cycle.

Diagrams 320-340 illustrate how decreasing the pressure of one or more phases of the ALD cycle may decrease the temperature of the substrate during at least a portion of the dose phase. In diagram 320, purge phase 320D is performed at a low pressure, while dose phase 320A, purge phase 320B, and conversion phase 320C are performed at a higher pressure. In some embodiments, purge phase 320D may be performed at a pressure less than about 1 Torr, less than about 0.5 Torr, less than about 0.1 Torr, or about 10 mTorr. In some embodiments, phases 320A-C may be performed at a pressure of at least about 1 Torr, at least about 5 Torr, or at least about 10 Torr. As shown in the temperature chart, during purge phase 320D the temperature of the substrate decreases from about 610° C. to about 520° C. In the subsequent dose phase 320A, the temperature of the substrate may increase as the pressure of the process chamber increases until it reaches equilibrium with, e.g., a pedestal supporting the wafer, such that the wafer is at about 610° C. Purge phase 320B and conversion phase 320C may be performed at this wafer temperature and process chamber pressure. This cycle may be repeated, such that each pre-dose purge phase is at a low pressure that reduces the temperature of the substrate for a subsequent dose phase.

Diagram 330 presents another example of ALD cycle phases according to embodiments herein. For diagram 330, purge phase 330D may be the same as purge phase 320D. Dose phase 330A may also be performed at a low pressure. Notably, the chamber pressure during dose phase 330A may be higher than the chamber pressure during purge phase 330D. The chamber pressure during dose phase 330A may be based on maintaining the temperature of the substrate, rather than decreasing or increasing the temperature of the substrate. As shown in the temperature diagram, during dose phase 330A the temperature of the substrate stays substantially the same. In other embodiments the temperature of the substrate may increase during dose phase 330A, but at a slower rate than if the chamber pressure was not lowered, e.g., a slower rate than during dose phase 320A. The process chamber pressure during dose phase 330A may be between the pressure of the process chamber during purge phase 320D and the pressure of the process chamber during phases 320B-C. In some embodiments, the pressure during phase 330A may be at least about 1 Torr, about 1 Torr, or between about 1 Torr and about 10 Torr.

As the substrate temperature remains low during dose phase 330A, the temperature of the substrate may increase during purge phase 330B prior to a conversion phase 330C. As it is desirable to have the conversion phase performed at a high substrate temperature, purge phase 330B may be performed for a sufficient duration to allow the temperature of the wafer to increase back to a high temperature at thermal equilibrium with the pedestal, e.g., about 610° C.

Diagram 340 presents another example of ALD cycle phases according to embodiments herein. Phases 340A, 340B, and 340D may be performed under the same process chamber pressure as diagram 330 (as shown, or alternatively the same process conditions as diagram 320). Conversion phase 340C may be performed in the presence of a plasma to further increase the temperature of the substrate during conversion. By igniting a plasma at a high power, e.g., at least about 2000 W, at least about 3000 W, at least about 5000 W, or at least about 6000 W, the substrate temperature may be further increased to, e.g., about 640° C. In some embodiments, power to the electrodes powering the plasma may subsequently be decreased/removed during purge phase 340D so that the temperature of the substrate may be decreased prior to a subsequent dose step at a low substrate temperature.

Notably, while the temperature of the substrate changes in each of diagrams 320-340, the temperature change is a result of changing the pressure of the process chamber, rather than causing any of the heating elements in the process chamber, e.g., the pedestal, to change. Cooling the substrate by changing the pressure may be more effective and efficient than adjusting power delivered to heating elements, resulting in an ALD process where the precursor may be adsorbed onto a surface of a substrate at a different temperature of the substrate than a subsequent conversion step where the substrate is exposed to reactant at a temperature higher than a pyrolysis temperature of the precursor.

Processes described herein may be used to deposit various films, including silicon-containing films, carbon-containing films, metal films, or other dielectric films. In some embodiments, films deposited according to processes described herein may be silicon oxide films, silicon nitride films, or silicon oxynitride films. In particular, processes described herein may be used to deposit films where a precursor to be adsorbed onto a surface of a substrate has a pyrolysis temperature below the temperature of a conversion step where the adsorbed precursor is exposed to a reactant. In one instance, the methods can provide a conformal SiN film, which in turn is deposited on a high aspect ratio (HAR) structure. In one embodiment, the aspect ratio (of depth to width) is about 30:1 or greater. After the ALD process, the obtained film can be a conformal film (e.g., having 100% step coverage).

In some embodiments, the methods herein provide enhanced growth rate of a film that is deposited on a side wall. Lower temperature precursor exposure processes may improve the growth rate compared to a process that exposes the substrate to precursors at a higher temperature. Thus, in some embodiments, a low temperature dose and high temperature conversion process as described herein may enhance growth rates of films, improving throughput.

For depositing silicon-containing films, one or more silicon-containing precursors may be used. Silicon-containing precursors suitable for use in accordance with disclosed embodiments include polysilanes (H₃Si—(SiH₂)ₙ—SiH₃), where n≥0. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R4, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino-1,1-dimethyl disiloxane, 1-N-methylethylamino-1,1-dimethyl disiloxane, 1-N methylpropylamino-1,1-dimethyl disiloxane, 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₅H₁₉N), cyclopropylamine (C₃H₅NH₂), sec-butylamine (C₄H₁₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂₀N₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

Where the protective film includes carbon, a carbon-containing reactant may be used. Examples of carbon-containing reactants include, but are not limited to, hydrocarbons (CₓH_{y}) oxygen-containing hydrocarbons (CₓH_{y}O_{z}), carbonyl sulfide (COS), carbon disulfide (CS₂), fluorocarbons (CₓF_{y}), hydrofluorocarbons (CₓH_{y}F_{z}), etc.

Where the protective film includes sulfur, a sulfur-containing reactant may be used. Examples of sulfur-containing reactants include, but are not limited to, hydrogen sulfide (H₂S), carbonyl sulfide (COS), etc.

Where the protective film includes metal, a metal-containing reactant may be used. Example metals include, but are not limited to, tungsten, tin, and molybdenum.

Example tungsten-containing reactants include, but are not limited to, bis(butylcyclopentadienyl)tungsten(IV) diiodide (C₁₈H₂₆I₂W); bis(tert-butylimino)bis(tert-butylamino)tungsten ((C₄H₉NH)₂W(C₄H₉N)₂); bis(tert-butylimino)bis(dimethylamino)tungsten(VI) (((CH₃)₃CN)₂W(N(CH₃)₂)₂); bis(cyclopentadienyl)tungsten(IV) dichloride (C₁₀H₁₀Cl₂W); bis(cyclopentadienyl)tungsten(IV) dihydride (C₁₀H₁₂W); bis(isopropylcyclopentadienyl)tungsten(IV) dihydride ((C₅H₄CH(CH₃)₂)₂WH₂); cyclopentadienyltungsten(II) tricarbonyl hydride (C₈H₆O₃W); tetracarbonyl(1,5-cyclooctadiene)tungsten(0) (C₁₂H₁₂O₄W); triamminetungsten(IV) tricarbonyl ((NH₃)₃W(CO)₃); tungsten hexacarbonyl (W(CO)₆), etc.

Example tin-containing reactants include, but are not limited to, bis[bis(trimethylsilyl)amino]tin(II) ([[(CH₃)₃Si]₂N]₂Sn); hexaphenylditin(IV) ([(C₆H₅)₃Sn]₂); tetraallyltin ((H₂C═CHCH₂)₄Sn); tetrakis(diethylamido)tin(IV) ([(C₂H₅)₂N]₄Sn); tetrakis(dimethylamido)tin(IV) ([(CH₃)₂N]₄Sn); tetramethyltin (Sn(CH₃)₄); tetravinyltin (Sn(CH═CH₂)₄); tin(II) acetylacetonate (C₁₀H₁₄O₄Sn); trimethyl(phenylethynyl)tin (C₆H₅C≡CSn(CH₃)₃); trimethyl(phenyl)tin (C₆H₅Sn(CH₃)₃), etc.

Example molybdenum-containing reactants include, but are not limited to, (bicyclo[2.2.1]hepta-2,5-diene)tetracarbonylmolybdenum(0) (C₁H₈MoO₄); bis(cyclopentadienyl)molybdenum(IV) dichloride (C₁₀H₁₀Cl₂Mo); cyclopentadienylmolybdenum(II) tricarbonyl (C₁₆H₁₀Mo₂O₆); molybdenumhexacarbonyl (Mo(CO)₆); (propylcyclopentadienyl)molybdenum(I) tricarbonyl (C₂₂H₂₂Mo₂O₆), etc.

Example ruthenium-containing reactants include, but are not limited to, bis(cyclopentadienyl)ruthenium(II) (C₁₀H₁₀Ru); bis(ethylcyclopentadienyl)ruthenium(II) (C₇H₉RuC₇H₉); triruthenium dodecacarbonyl (Ru₃(CO)₁₂), etc.

Example aluminum-containing reactants include, but are not limited to, aluminum tris(2,2,6,6-tetramethyl-3,5-heptanedionate) (Al(OCC(CH₃)₃CHCOC(CH₃)₃)₃); triisobutylaluminum ([(CH₃)₂CHCH₂]₃Al); trimethylaluminum ((CH₃)₃Al); tris(dimethylamido)aluminum(III) (Al(N(CH₃)₂)₃), etc.

Example zirconium-containing reactants include, but are not limited to, bis(cyclopentadienyl)zirconium(IV) dihydride (C₁₀H₁₂Zr); bis(methyl-η5-cyclopentadienyl)methoxymethylzirconium (Zr(CH₃C₅H₄)₂CH₃OCH₃); dimethylbis(pentamethylcyclopentadienyl)zirconium(IV) (C₂₂H₃₆Zr); tetrakis(diethylamido)zirconium(IV) ([(C₂H₅)₂N]₄Zr); tetrakis(dimethylamido)zirconium(IV) ([(CH₃)₂N]₄Zr); tetrakis(dimethylamido)zirconium(IV) ([(CH₃)₂N]₄Zr); tetrakis(ethylmethylamido)zirconium(IV) (Zr(NCH₃C₂H₅)₄); zirconium(IV) dibutoxide(bis-2,4-pentanedionate) (C₁₈H₃₂O₆Zr); zirconium(IV) 2-ethylhexanoate (Zr(C₈H₁₅O₂)₄); zirconium tetrakis(2,2,6,6-tetramethyl-3,5-heptanedionate) (Zr(OCC(CH₃)₃CHCOC(CH₃)₃)₄), etc.

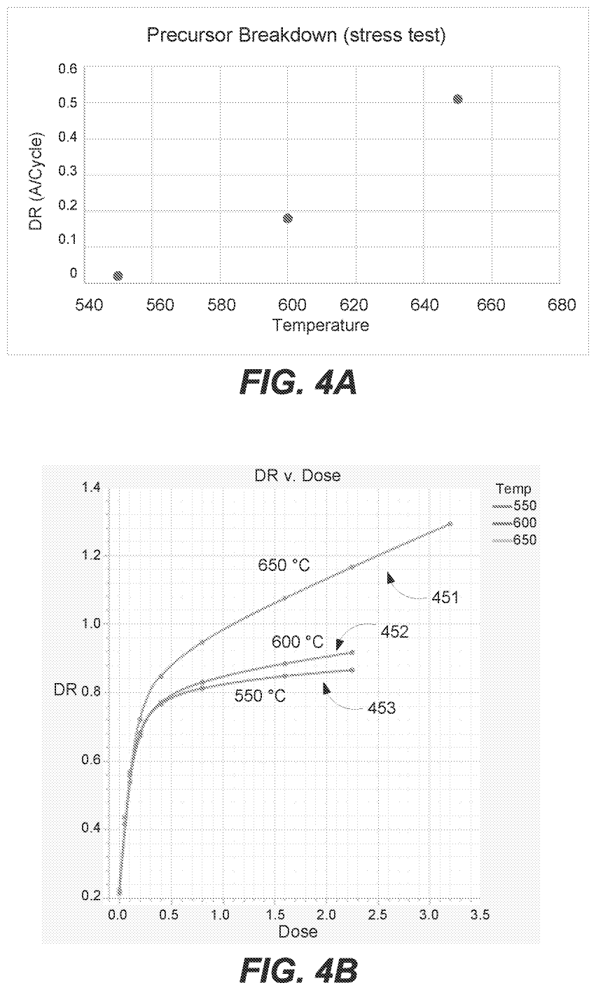

FIGS. 4A and 4B present example methods of determining a pyrolysis temperature of a precursor. Other methods may be known to those having skill in the art. In FIG. 4A, the temperature of the substrate is held substantially constant and repeated precursor/purge phases are performed without exposing the substrate to a reactant. As the substrate is not exposed to reactant, additional precursor exposure phases would not result in a film deposition as the surface is already saturated. Thus, as shown in FIG. 4A, at about 550° C. the deposition rate (DR) is near zero, as this is below the pyrolysis temperature of the precursor such that additional exposure of precursor does not result in any film growth. By comparison, at 600° C. or 650° C. there is a noticeable deposition rate, indicating a CVD component that is causing film growth in the absence of a reactant. By performing repeated precursor/purge cycles at various temperatures, a pyrolysis temperature of the precursor may be determined.

FIG. 4B presents a different method of determining a pyrolysis temperature. FIG. 4B presents a time/deposition rate chart, where each of lines 451, 452, and 453 correspond to a different temperature. Increasing the dose/exposure time of the substrate to a precursor should have diminishing effects on the deposition rate as the surface saturates. Once the surface is sufficiently saturated with precursor, additional exposure time should not increase the deposition rate. However, as seen with line 451, additional exposure time causes a linear increase in deposition rate, indicating a CVD component. In particular, the CVD component may be measured as the slope of the linear portion of line 451, i.e. between about 0.5 and 3 seconds. By changing the temperature of the substrate the pyrolysis temperature may be determined based on a temperature having a diminishing slope of the line, e.g., negative second derivative.

### Apparatus

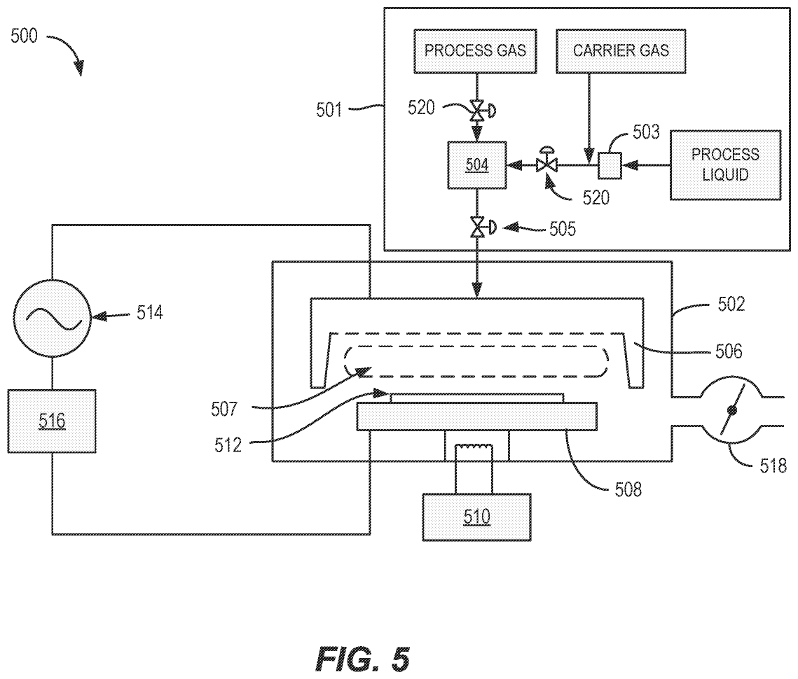

FIG. 5 schematically shows an embodiment of a process station 500 that may be used to deposit material using atomic layer deposition (ALD) and/or chemical vapor deposition (CVD), either of which may be plasma enhanced. For simplicity, the process station 500 is depicted as a standalone process station having a process chamber body 502 for maintaining a low-pressure environment. However, it will be appreciated that a plurality of process stations 500 may be included in a common process tool environment. Further, it will be appreciated that, in some embodiments, one or more hardware parameters of process station 500, including those discussed in detail below, may be adjusted programmatically by one or more computer controllers.

Process station 500 fluidly communicates with reactant delivery system 501 for delivering process gases to a distribution showerhead 506. Reactant delivery system 501 includes a mixing vessel 504 for blending and/or conditioning process gases for delivery to showerhead 506. One or more mixing vessel inlet valves 520 may control introduction of process gases to mixing vessel 504. Similarly, a showerhead inlet valve 505 may control introduction of process gasses to the showerhead 506. In some embodiments, an inhibitor or other gas may be directly delivered to the chamber body 502. One or more mixing vessel inlet valves 520 may control introduction of process gases to mixing vessel 504. These valves may be controlled depending on whether a process gas, inhibition gas, or carrier gas may be turned on during various operations. In some embodiments, an inhibition gas may be generated by using an inhibition liquid and vaporizing using a heated vaporizer.

As an example, the embodiment of FIG. 5 includes a vaporization point 503 for vaporizing liquid reactant to be supplied to mixing vessel 504. In some embodiments, vaporization point 503 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 100° C. to approximately 150° C. at mixing vessel 504.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller (LFC) upstream of vaporization point 503 may be provided for controlling a mass flow of liquid for vaporization and delivery to process station 500. For example, the liquid flow controller may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 506 distributes process gases toward substrate 512. In the embodiment shown in FIG. 5, substrate 512 is located beneath showerhead 506, and is shown resting on a pedestal 508. It will be appreciated that showerhead 506 may have any suitable shape, and may have any suitable number and arrangement of ports for distributing processes gases to substrate 512.

In some embodiments, a microvolume 507 is located beneath showerhead 506. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 508 may be raised or lowered to expose substrate 512 to microvolume 507 and/or to vary a volume of microvolume 507. For example, in a substrate transfer phase, pedestal 508 may be lowered to allow substrate 512 to be loaded onto pedestal 508. During a deposition process phase, pedestal 508 may be raised to position substrate 512 within microvolume 507. In some embodiments, microvolume 507 may completely enclose substrate 512 as well as a portion of pedestal 508 to create a region of high flow impedance during a deposition process.

Optionally, pedestal 508 may be lowered and/or raised during portions the deposition process to modulate process pressure, reactant concentration, etc., within microvolume 507. In one scenario where process chamber body 502 remains at a base pressure during the deposition process, lowering pedestal 508 may allow microvolume 507 to be evacuated. Example ratios of microvolume to process chamber volume include, but are not limited to, volume ratios between 1:600 and 1:10. It will be appreciated that, in some embodiments, pedestal height may be adjusted programmatically by a suitable computer controller.

In another scenario, adjusting a height of pedestal 508 may allow a plasma density to be varied during plasma activation and/or treatment cycles included in the deposition process. At the conclusion of the deposition process phase, pedestal 508 may be lowered during another substrate transfer phase to allow removal of substrate 512 from pedestal 508.

While the example microvolume variations described herein refer to a height-adjustable pedestal, it will be appreciated that, in some embodiments, a position of showerhead 506 may be adjusted relative to pedestal 508 to vary a volume of microvolume 507. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers.

Showerhead 506 and pedestal 508 electrically communicate with RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are included above. Likewise, RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 508 may be temperature controlled via heater 510. In some embodiments, heater 510 may be set to a single temperature during ALD cycles as described herein, despite the substrate temperature varying during ALD cycles as a result of pressure changes in the process chamber. Further, in some embodiments, pressure control for deposition process station 500 may be provided by butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to process station 500.

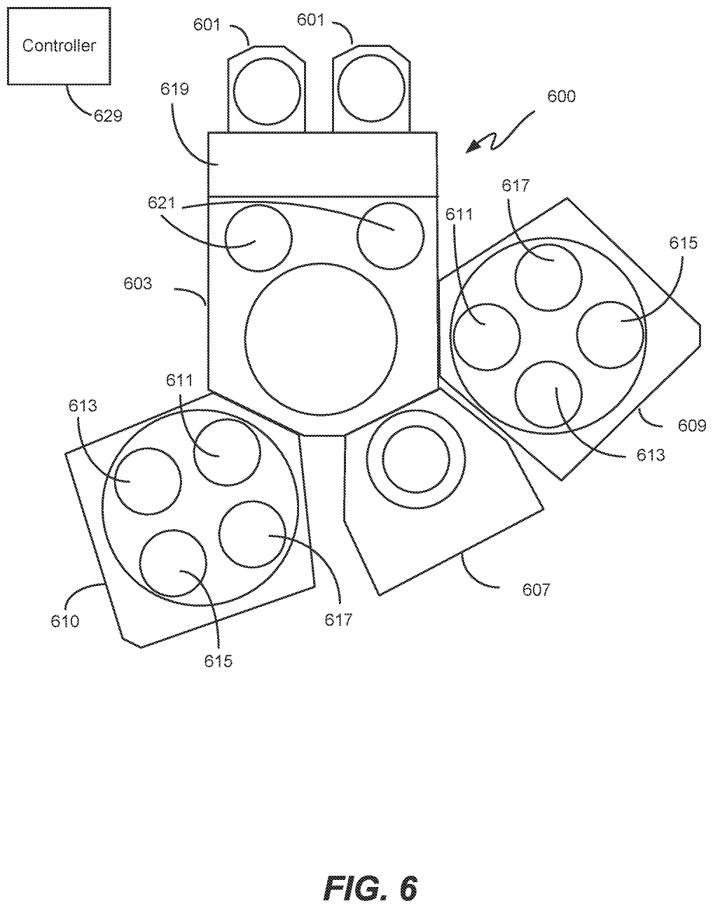

FIG. 6 is a block diagram of a processing system suitable for conducting thin film deposition processes in accordance with certain embodiments. The system 600 includes a transfer module 603. The transfer module 603 provides a clean, pressurized environment to minimize risk of contamination of substrates being processed as they are moved between various reactor modules. Mounted on the transfer module 603 are two multi-station reactors 609 and 610, each capable of performing atomic layer deposition (ALD) and/or chemical vapor deposition (CVD) according to certain embodiments. Reactors 609 and 610 may include multiple stations 611, 613, 615, and 617 that may sequentially or non-sequentially perform operations in accordance with disclosed embodiments. The stations may include a heated pedestal or substrate support, one or more gas inlets or showerhead or dispersion plate.

Also mounted on the transfer module 603 may be one or more single or multi-station modules 607 capable of performing plasma or chemical (non-plasma) pre-cleans, or any other processes described in relation to the disclosed methods. The module 607 may in some cases be used for various treatments to, for example, prepare a substrate for a deposition process. The module 607 may also be designed/configured to perform various other processes such as etching or polishing. The system 600 also includes one or more wafer source modules 601, where wafers are stored before and after processing. An atmospheric robot (not shown) in the atmospheric transfer chamber 619 may first remove wafers from the source modules 601 to loadlocks 621. A wafer transfer device (generally a robot arm unit) in the transfer module 603 moves the wafers from loadlocks 621 to and among the modules mounted on the transfer module 603.

In various embodiments, a system controller 629 is employed to control process conditions during deposition. The controller 629 will typically include one or more memory devices and one or more processors. A processor may include a CPU or computer, analog and/or digital input/output connections, stepper motor controller boards, etc.

The controller 629 may control all of the activities of the deposition apparatus. The system controller 629 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 629 may be employed in some embodiments.

Typically there will be a user interface associated with the controller 629. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 629. The signals for controlling the process are output on the analog and digital output connections of the deposition apparatus 600.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 629 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 629, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

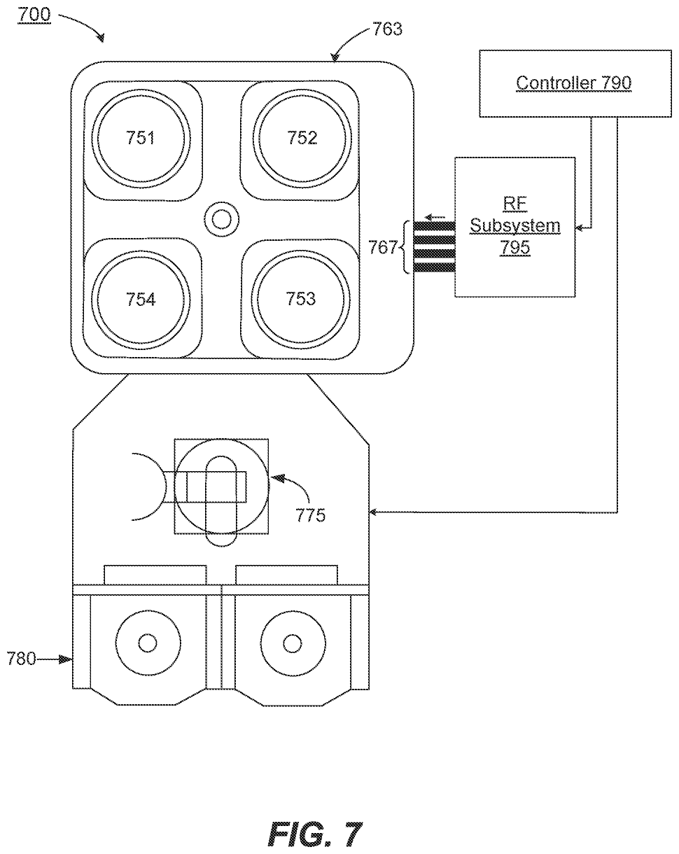

It may be appreciated that a plurality of process stations may be included in a multi-station processing tool environment, such as shown in FIG. 7, which depicts a schematic view of an embodiment of a multi-station processing tool. Processing apparatus 700 employs an integrated circuit fabrication chamber 763 that includes multiple fabrication process stations, each of which may be used to perform processing operations on a substrate held in a wafer holder, such as a pedestal, at a particular process station. In the embodiment of FIG. 7, the integrated circuit fabrication chamber 763 is shown having four process stations 751, 752, 753, and 754. Other similar multi-station processing apparatuses may have more or fewer process stations depending on the implementation and, for example, a desired level of parallel wafer processing, size/space constraints, cost constraints, etc. Also shown in FIG. 7 is substrate handler robot 775, which may operate under the control of system controller 790, configured to move substrates from a wafer cassette (not shown in FIG. 7) from loading port 780 and into integrated circuit fabrication chamber 763, and onto one of process stations 751, 752, 753, and 754.

FIG. 7 also depicts an embodiment of a system controller 790 employed to control process conditions and hardware states of processing apparatus 700. System controller 790 may include one or more memory devices, one or more mass storage devices, and one or more processors, as described herein.

RF subsystem 795 may generate and convey RF power to integrated circuit fabrication chamber 763 via radio frequency input ports 767. In particular embodiments, integrated circuit fabrication chamber 763 may comprise input ports in addition to radio frequency input ports 767 (additional input ports not shown in FIG. 7). Accordingly, integrated circuit fabrication chamber 763 may utilize 8 RF input ports. In particular embodiments, process stations 751-754 of integrated circuit fabrication chamber 763 may each utilize first and second input ports in which a first input port may convey a signal having a first frequency and in which a second input port may convey a signal having a second frequency. Use of dual frequencies may bring about enhanced plasma characteristics.

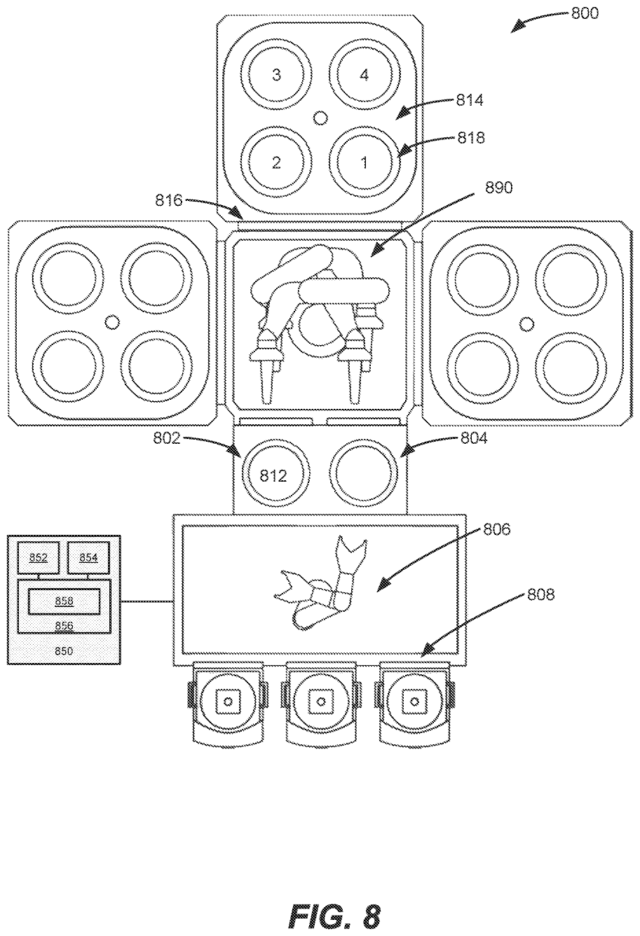

As described above, one or more process stations may be included in a multi-station processing tool. FIG. 8 shows a schematic view of an embodiment of a multi-station processing tool 800 with an inbound load lock 802 and an outbound load lock 804, either or both of which may comprise a remote plasma source. A robot 806, at atmospheric pressure, is configured to move substrates or wafers from a cassette loaded through a pod 808 into inbound load lock 802 via an atmospheric port. A substrate is placed by the robot 806 on a pedestal 812 in the inbound load lock 802, the atmospheric port is closed, and the load lock is pumped down. Where the inbound load lock 802 comprises a remote plasma source, the substrate may be exposed to a remote plasma treatment in the load lock prior to being introduced into a processing chamber 814. Further, the substrate also may be heated in the inbound load lock 802 as well, for example, to remove moisture and adsorbed gases. Next, a chamber transport port 816 to processing chamber 814 is opened, and another robot 890 places the substrate into the reactor on a pedestal of a first station shown in the reactor for processing. While the embodiment depicted in FIG. 8 includes load locks, it will be appreciated that, in some embodiments, direct entry of a substrate into a process station may be provided. In various embodiments, the soak gas is introduced to the station when the substrate is placed by the robot 806 on the pedestal 812.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 814 may include one or more matched pairs of ALD and plasma-enhanced ALD process stations. While the depicted processing chamber 814 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 depicts an embodiment of a wafer handling system 890 for transferring substrates within processing chamber 814. In some embodiments, wafer handling system 890 may transfer substrates between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc. In some embodiments, system controller 850 includes machine-readable instructions for performing operations such as those described herein.

In some embodiments, system controller 850 controls the activities of process tool 800. System controller 850 executes system control software 858 stored in mass storage device 854, loaded into memory device 856, and executed on processor 852. Alternatively, the control logic may be hard coded in the system controller 850. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 858 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 800. System control software 858 may be configured in any suitable way. For example, various process tool component subroutines or control objects may be written to control operation of the process tool components used to carry out various process tool processes. System control software 858 may be coded in any suitable computer readable programming language.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of depositing a film, the method comprising:
providing a substrate in a process chamber; and
performing one or more cycles of an atomic layer deposition (ALD) process, wherein each of the one or more cycles of the ALD process comprises:
(a) exposing the substrate to a precursor, wherein the substrate is at a first temperature during at least a portion of (a), wherein the first temperature is below a pyrolysis temperature of the precursor; and
(b) exposing the substrate to one or more reactants, wherein during at least a portion of (b) the substrate is at a second temperature above the pyrolysis temperature.

2. The method of claim 1, wherein during (b) the process chamber is at a first pressure, and the method further comprises, before (a):
(c) exposing the substrate to a purge gas, wherein during (c) the process chamber is at a second pressure less than the first pressure.

3. The method of claim 2, wherein during (c) the temperature of the substrate decreases from the second temperature to the first temperature.

4. The method of claim 2, wherein a duration of (c) is at least about 5 seconds.

5. The method of claim 2, wherein the first pressure is at least about 5 Torr, and the second pressure is less than about 1 Torr.

6. The method of claim 5, wherein the second pressure is less than about 0.1 Torr.

7. The method of claim 2, wherein the process chamber is at a third pressure during (a), and the third pressure is less than the first pressure.

8. The method of claim 2, wherein the purge gas comprises an inert gas.

9. The method of claim 2, wherein the purge gas comprises H₂.

10. The method of claim 1, wherein the second temperature is at least about 600° C.

11. The method of claim 1, wherein the pyrolysis temperature is between about 500° C. and about 600° C.

12. The method of claim 1, wherein (b) is performed in the presence of a plasma.

13. The method of claim 12, wherein a power of the plasma is at least about 5000 W.

14. The method of claim 1, wherein the precursor is a silicon-containing precursor.

15. The method of claim 1, wherein the precursor is a carbon-containing precursor.

16. The method of claim 1, wherein the one or more reactants comprise a nitrogen-containing reactant.

17. The method of claim 1, wherein the one or more reactants comprise an oxygen-containing reactant.

18. The method of claim 1, wherein the ALD process forms a conformal film.

19. The method of claim 18, wherein the conformal film is a silicon nitride film.

20. The method of claim 1, wherein the substrate comprises features having an aspect ratio of at least about 30:1.

21. The method of claim 1, wherein process chamber comprises a pedestal, and the pedestal temperature is about the second temperature during (a).
